(19) United States
(12) Patent Application Publication
(10) Pub. No.: US 2025/0210596 A1
(43) Pub. Date: Jun. 26, 2025

(54) POWER MODULE WITH STACKED STRUCTURE AND CAPACITOR ASSEMBLY LAYER

(71) Applicant: Monolithic Power Systems, Inc., Kirkland, WA (US)

(72) Inventor: Ting Ge, San Jose, CA (US)

(21) Appl. No.: 19/079,185

(22) Filed: Mar. 13, 2025

Related U.S. Application Data
(63) Continuation-in-part of application No. 18/469,800, filed on Sep. 19, 2023.

(51) Int. Cl. H01L 25/07; H01L 23/367; H10D 1/20; H10D 80/20

(52) U.S. Cl. CPC H01L 25/074; H10D 1/20; H10D 80/215; H01L 23/3672

(57) ABSTRACT

A power module has a first layer, a second layer, and an inductor assembly. The first layer has a plurality of connecting pillars, a first plurality of capacitors electrically connected in parallel between an input node and a reference ground, and a second plurality of capacitors electrically connected in parallel between an output node and the reference ground. The second layer is attached between the first layer and the inductor assembly, having a first pair of switches forming a first switch node, and a second pair of switches forming a second switch node. The first pair of switches and the second pair of switches are electrically connected between the input node and the reference ground. The inductor assembly has a first inductor electrically connected between the output node and the first switch node and a second inductor electrically connected between the output node and the second switch node.

### CROSS-REFERENCE TO RELATED APPLICATIONS

The present application is a continuation-in-part of U.S. application Ser. No. 18/469,800 filed on Sep. 19, 2023, which is incorporated herein by reference in its entirety.

### BACKGROUND OF THE INVENTION

### 1. Field of the Invention

The present invention relates generally to electronic components, and more particularly but not exclusively to power modules.

### 2. Description of Related Art

Power converter, as known in the art, converts an input power to an output power for providing a load with required voltage and current. Multi-phase power converter comprising a plurality of paralleled power stages operating out of phase has lower output ripple voltage, better transient performance and lower ripple-current-rating requirements for input capacitors. They are widely used in high current and low voltage applications, such as server, microprocessor.

With the development of modern GPUs (Graphics Processing Units), and CPUs (Central Processing Units), increasingly high load current is required to achieve better processor performance. Besides, to improve integration density of the terminal products like CPUs and GPUs, the size of their power converters needs to be smaller. Higher current and smaller size put more challenges to the heat conduction of the power converters. Therefore, high-power density and high-efficiency power modules with excellent heat dissipation path are necessary for the processers.

### SUMMARY OF THE INVENTION

It is an object of the present invention to provide a power module with a stacked structure integrating inductors, power integrated circuits (ICs) dies, input capacitors, and output capacitors.

Embodiments of the present invention are directed to a power module comprising a first layer, a second layer, and an inductor assembly. The first layer comprises a first plurality of capacitors, a second plurality of capacitors, and a plurality of connecting pillars. The first plurality of capacitors are electrically connected in parallel between an input node and a reference ground, and the second plurality of capacitors are electrically connected in parallel between an output node and the reference ground. The second layer comprises a lower surface attached to the first layer, an upper surface opposite the lower surface, a first power IC die, and a second power IC die. The first power IC die has a first pair of switches electrically connected between the input node and the reference ground, and the second power IC die has a second pair of switches electrically connected between the input node and the reference ground. The inductor assembly is attached to the upper surface of the second layer, comprising a magnetic core, a first winding passing through the magnetic core, and a second winding passing through the magnetic core. The first winding has a first end electrically connected to the output node and a second end electrically connected to a first switch node formed by the first pair of switches, and the second winding has a first end electrically connected to the output node and a second end electrically connected to a second switch node formed by the second pair of switches.

Embodiments of the present invention are directed to a power module comprising a first layer, a second layer, and an inductor assembly. The first layer comprises a first plurality of capacitors, a second plurality of capacitors, and a plurality of connecting pillars. The first plurality of capacitors are electrically connected in parallel between an input node and a reference ground, and the second plurality of capacitors are electrically connected in parallel between an output node and the reference ground. The second layer comprises a lower surface attached to the first layer, an upper surface opposite the lower surface, a first pair of switches, and a second pair of switches. The first pair of switches and the second pair of switches are electrically connected between the input node and the reference ground. The inductor assembly is attached to the upper surface of the second layer, comprising a first inductor and a second inductor. The first inductor is electrically connected between the output node and a first switch node formed by the first pair of switches, and the second inductor is electrically connected between the output node and a second switch node formed by the second pair of switches.

Embodiments of the present invention are directed to a power module, comprising a capacitor assembly layer, a first pair of switches, a second pair of switches, and an inductor assembly. The capacitor assembly layer is disposed at bottom of the power module, comprising a bottom substrate, a first plurality of capacitors, and a second plurality of capacitors. The first plurality of capacitors and the second plurality of capacitors are disposed on the bottom substrate. The first plurality of capacitors are electrically connected in parallel between an input node and a reference ground, and the second plurality of capacitors are electrically connected in parallel between an output node and the reference ground. The inductor assembly is disposed at top of the power module, comprising a magnetic core, a first winding at least partially embedded in the magnetic core, and a second winding at least partially embedded in the magnetic core. The first winding is electrically connected between an output node and a first switch node formed by the first pair of switches, and the second winding is electrically connected between the output node and a second switch node formed by the second pair of switches.

These and other features of the present invention will be readily apparent to persons of ordinary skill in the art upon reading the entirety of this disclosure, which includes the accompanying drawings and claims.

### BRIEF DESCRIPTION OF THE DRAWINGS

The present invention can be further understood with reference to following detailed description and appended drawings, wherein like elements are provided with like reference numerals. These drawings are only for illustration purpose, thus may only show part of the devices and are not necessarily drawn to scale.

FIG. 1 schematically shows a prior art multi-phase power converter 10 which comprises a controller 101, N power devices 103 and N inductors L for supplying power to a load 104.

FIG. 2 shows a power module 20 for a dual-phase power converter in accordance with an embodiment of the present invention.

FIG. 3 shows a disassembled and perspective view illustrating the power module 20 of FIG. 1.

FIG. 4 shows a cross-sectional view illustrating the power module 20 taken along AA' line of FIG. 1 in accordance with an embodiment of the present invention.

FIG. 5 shows a bottom view of the inductor assembly 203 in accordance with an embodiment of the present invention.

FIG. 6 shows a top view of the device substrate 202 in accordance with an embodiment of the present invention.

FIG. 7 shows a bottom view of the device substrate 202 in accordance with an embodiment of the present invention.

FIG. 8 shows a bottom view of the bottom substrate 201 in accordance with an embodiment of the present invention.

FIG. 9 is a side view illustrating a system 90 employing the power module 20 in accordance with an embodiment of the present invention.

FIG. 10 schematically shows a multi-phase power converter 30 in accordance with an embodiment of the present invention.

FIG. 11 shows a power module 40 in accordance with an embodiment of the present invention.

FIG. 12 shows a power module 40B in accordance with another embodiment of the present invention.

FIG. 13 shows a disassembled and perspective view illustrating the power module 40 of FIG. 11 in accordance with an embodiment of the present invention.

FIG. 14 shows a cross-sectional view illustrating the power module 40 taken along BB' line of FIG. 11 in accordance with an embodiment of the present invention.

FIG. 15 shows a bottom view of a die substrate 421 of the power module 40 in accordance with an embodiment of the present invention.

FIG. 16 shows a top view of a capacitor assembly 43 of the power module 40 in accordance with an embodiment of the present invention.

FIG. 17 shows a bottom view of the capacitor assembly 43 in accordance with an embodiment of the present invention.

### DETAILED DESCRIPTION

In the present disclosure, numerous specific details are provided, such as examples of electrical circuits and components, to provide a thorough understanding of embodiments of the invention. Persons of ordinary skill in the art will recognize, however, that the invention can be practiced without one or more of the specific details. It is noted that, for purposes of illustrative clarity, certain elements in the drawings may not be drawn to scale. In other instances, well-known details are not shown or described to avoid obscuring aspects of the invention.

Throughout the specification and claims, the terms “left”,“right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

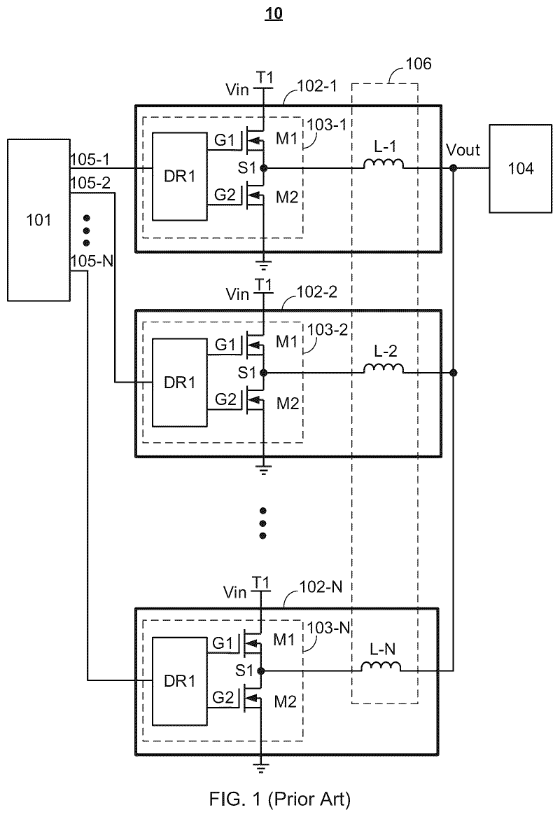

FIG. 1 schematically shows a prior art multi-phase power converter 10 which comprises a controller 101, N power blocks 103-1˜103-N and N inductors L-1˜L-N for supplying power to a load 104, wherein N is an integer, and N≥1. Each power block 103 and one inductor L represent one power stage, i.e., one phase 102 of the power converter 10, as shown in FIG. 1. Each power block 103 includes switches M1, M2 and a driver DR1 for providing driving signals G1 and G2 to drive the switches M1 and M2 respectively. The controller 101 provides N phase control signals 105-1˜105-N respectively to N power blocks 103-1˜103-N to control the N phases 102-1˜102-N working out of phase, i.e., each one of the inductors L-1˜L-N sequentially absorb power from the input source and sequentially deliver power to the load 104. It should be noticed that the outputs of all phases as shown in FIG. 1 are connected to work as a multi-phase converter. However, each phase output may be separated to work as multiple independent converters which could have different output voltage levels for different load demands.

The power stage 102 with Buck topology is shown in FIG. 1 for example. Persons of ordinary skill in the art should appreciate that power stages with other topologies, like Boost topology, Buck-Boost topology could also be adopted in a multi-phase power converter.

The inductors L-1˜L-N could be implemented by one or a few coupled inductors or could be implemented by N single inductors.

When N=2, the multi-phase power converter 10 is used as a dual-phase power converter or two separate single-phase converters. For the ease of description, dual-phase power module for a dual-phase power converter is discussed as an example to illustrate the present invention.

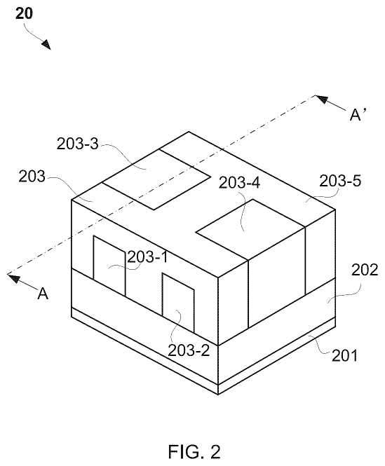

FIG. 2 shows a power module 20 for a dual-phase power converter in accordance with an embodiment of the present invention. The power module 20 may serve as the power stage 102 of FIG. 1, with N=2. The power module 20 includes a bottom substrate 201, a device substrate 202 and an inductor assembly 203. The bottom substrate 201 is arranged at the bottom of the power module 20. The device substrate 202 is arranged on the bottom substrate 201. The inductor assembly 203 is arranged on the device substrate 202. Power device chips integrating the components of the power blocks 103 shown in FIG. 1 is embedded within the device substrate 202. The inductors L are integrated in the inductor assembly 203.

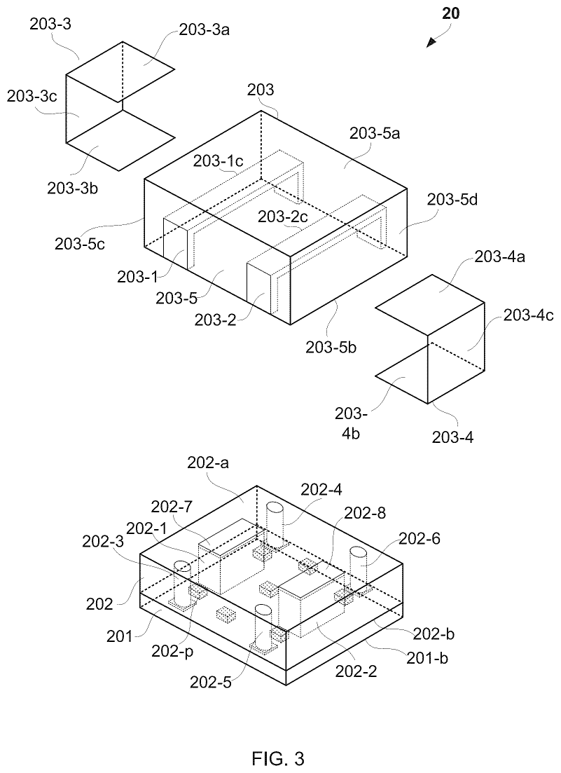

FIG. 3 shows a disassembled and perspective view illustrating the power module 20 of FIG. 2. As shown in FIG. 3, the device substrate 202 includes a first power device chip 202-1, a second power device chip 202-2, a first pair of connecting pillars 202-3 and 202-4, a second pair of connecting pillars 202-5 and 202-6, and a plurality of discrete components 202-p embedded within the device substrate 202. Each one of the first power device chip 202-1 and the second power device chip 202-2 integrates one power block 103 in FIG. 1, which includes the switches M1, M2, the driver DR1, and further integrates some auxiliary circuits not shown in FIG. 1. The first pair of the connecting pillars includes a first connecting pillar 202-3 and a second connecting pillar 202-4 arranged at opposite sides of the first power device chip 202-1. The second pair of the connecting pillars includes a third connecting pillar 202-5 and a fourth connecting pillar 202-6 arranged at opposite sides of the second power device chip 202-2. Each one of the connecting pillars has a first end connecting out of the device substrate 202, and connected to the corresponding winding of the inductor assembly 203, and a second end connected to the bottom substrate 201. The connecting pillars shown in the example of FIG. 3 are cylinders. It should be appreciated that any shape of the connecting pillars is applicable to the present invention. The discrete components 202-p include resistors and capacitors of the power converter 10, like the input capacitors at the input terminal T1 of the power converter 10 for receiving the input voltage Vin to provide pulse current, the filter capacitors and resistors for the drivers DR1 and internal logic circuits power supplies (not shown in FIG. 1), etc.

In the example of FIG. 3, the inductor assembly 203 includes a magnetic core 203-5, a first winding 203-1 and a second winding 203-2 passing through the magnetic core 203-5. The first winding 203-1 and the magnetic core 203-5 form a first inductor L-1 as shown in FIG. 1. The second winding 203-2 and the magnetic core 203-5 form a second inductor L-2 as shown in FIG. 1. Furthermore, the inductor assembly 203 includes a first inductor heat sink 203-3 and a second inductor heat sink 203-4, each of which has a “C” shape, and partially wraps the magnetic core 203-5. As can be seen from FIG. 3, the first inductor heat sink 203-3 has a first portion 203-3a partially covering a first surface 203-5a of the magnetic core 203-5, a second portion 203-3b partially covering a second surface 203-5b of the magnetic core 203-5, and a third portion 203-3c connecting the first portion 203-3a and the second portion 203-3b, and partially covering a third surface 203-5c of the magnetic core 203-5, wherein the first surface 203-5a and the second surface 203-5b are opposite, and the third surface 203-5c is vertical to the first surface 203-5a and the second surface 203-5b. The second inductor heat sink 203-4 has a first portion 203-4a partially covering the first surface 203-5a, a second portion 203-4b partially covering the second surface 203-5b, and a third portion 203-4c connecting the first portion 203-4a and the second portion 203-4b, and covering a fourth surface 203-5d of the magnetic core 203-5, wherein the fourth surface 203-5d is opposite to the third surface 203-5c, and is vertical to the first surface 203-5a and the second surface 203-5b of the magnetic core 203-5. The surfaces of the magnetic core 203-5 are also referred as surfaces of the inductor module 203. It should be appreciated that the first inductor heat sink 203-3 and the second inductor heat sink 203-4 are configured for transferring heat from the power device chips to the environment or external components. The shape of the first inductor heat sink 203-3 and the second inductor heat sink 203-4 may be varying in different applications, e.g., the first inductor heat sink 203-3 may have a “L” shape with the second portion 203-3b and the third portion 203-3c, and similarly, the second inductor heat sink 203-4 may have a “L” shape with the second portion 203-4b and the third portion 203-4c.

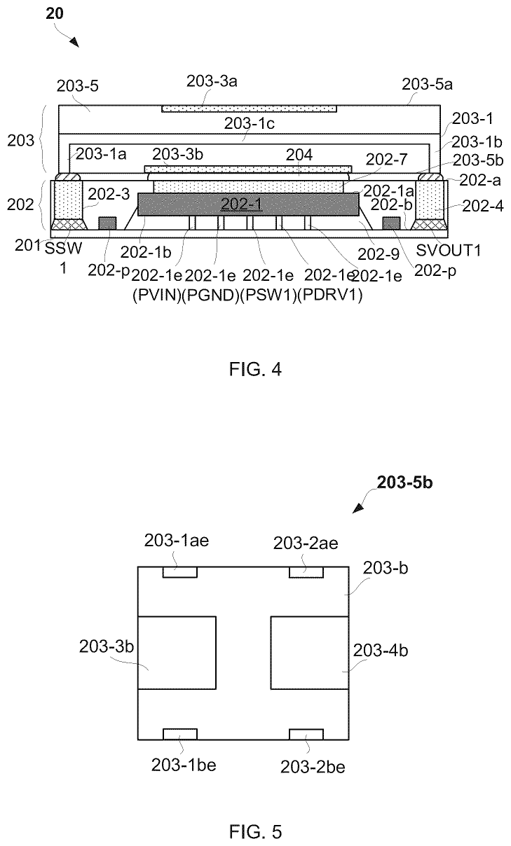

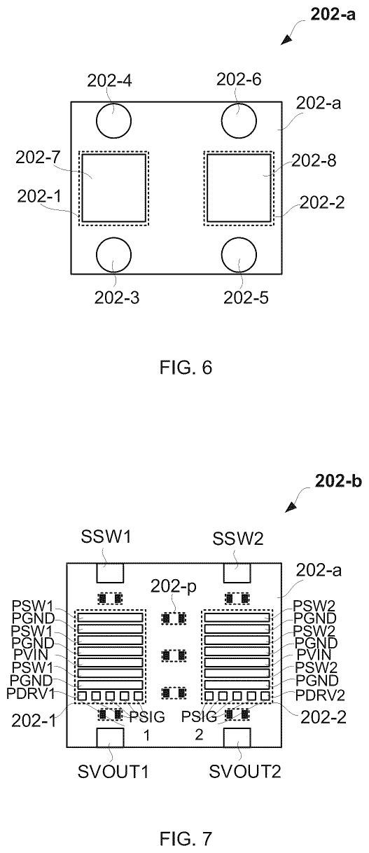

FIG. 4 shows a cross-sectional view illustrating the power module 20 taken along AA' line of FIG. 2 in accordance with an embodiment of the present invention. FIG. 5 shows a bottom view of the inductor assembly 203, i.e., the second surface 203-5b of the inductor assembly 203, in accordance with an embodiment of the present invention. FIG. 6 shows a top view of the device substrate 202, i.e., the first surface 202-a of the device substrate 202, in accordance with an embodiment of the present invention. FIG. 7 shows a bottom view of the device substrate 202, i.e., the second surface 202-b of the device substrate 202, in accordance with an embodiment of the present invention. The structure of the power module 20 will be illustrated with reference to FIGS. 3˜7.

As shown in FIG. 4, the first power device chip 202-1 has a first surface 202-1a and a second surface 202-1b. The first surface 202-1a is covered by a die heat sink 202-7 as shown in FIGS. 4 and 6, and the second surface 202-1b has a plurality of pins 202-1e (including pins PVIN, PGND, PSW1, PDRV1, and etc.) exposed on the second surface 202-b of the device substrate 202 as shown in FIGS. 4 and 7, and connected to the bottom substrate 201. Similarly, The first surface 202-2a of the second power device chip 202-2 is covered by a die heat sink 202-8 as shown in FIG. 6, and the second surface 202-2b of the second power device chip 202-2 has a plurality of pins 202-2e (including pins PVIN, PGND, PSW2, PDRV2, and etc.) exposed on the second surface 202-b of the device substrate 202 as shown in FIG. 7, and connected to the bottom substrate 201. It should be appreciated that the pins shown in FIGS. 4 and 7 are for illustration purpose. More pins may be configured in a real application. Furthermore, the pin shape, the pin size and the pin distribution would be varying in different applications. The die heat sink 202-7 and the die heat sink 202-8 are heat disposal layers, which are made of copper in one embodiment, and are made of other material in other embodiments. Persons of ordinary skill in the art should appreciate that any suitable layer configured to transfer heat from the power device chip is applicable as the die heat sink. In one embodiment, the first portion 203-3a of the first inductor heat sink 203-3 and the first portion 203-4a of the second inductor heat sink 203-4 are extending to each other and merged as one piece. In one embodiment, the second portion 203-3b of the first inductor heat sink 203-3 and the second portion 203-4b of the second inductor heat sink 203-4 are extending to each other and merged as one piece. In one embodiment, the first portion 203-3a of the first inductor heat sink 203-3 and the first portion 203-4a of the second inductor heat sink 203-4 are removed, and a heat radiator may remove heat from the first power device chip 202-1 and the second power device chip 202-2 via the third portion 203-3c of the first inductor heat sink 203-3 and the third portion 203-4c of the second inductor heat sink 203-4. Similarly, the die heat sink 202-7 and the die heat sink 202-8 could be merged as a whole piece.

As mentioned before, the first power device chip 202-1 integrates the switches M1, M2, the driver DR1 shown in FIG. 1, and other accessory circuits not shown in FIG. 1. The plurality of pins 202-1e of the first power device chip 202-1 includes at least an input pin PVIN, a switching pin PSW1, a ground pin PGND, and a driving pin PDRV1 as shown in FIG. 7. The first switch M1 has a first terminal coupled to the input pin PVIN (corresponding to the input terminal T1 in FIG. 1) to receive the input voltage Vin (shown in FIG. 1), a second terminal connected to the switching pin PSW1 (corresponding to the switching terminal S1 in FIG. 1), and a control terminal configured to receive a first driving signal G1. The second switch M2 has a first terminal connected to the switching pin PSW1, a second terminal connected to the ground pin PGND, and a control terminal configured to receive a second driving signal G2. The driver DR1 is coupled to the driving pin PDRV1 to receive a phase control signal 105, and to provide the first driving signal G1 and the second driving signal G2 based on the phase control signal 105. The plurality of pins of the power device chips 202-1 and 202-2 are connected to external circuits/devices/components via the bottom substrate 201. The bottom substrate 201 may be attached to a mainboard where the load (CPU, GPU, etc.) located, and there may be circuits/devices/components on the mainboard providing the input voltage Vin, the phase control signal 105, and a ground reference GND that provides a common ground for the first power device chip 202-1 and the second power device chip 202-2 via the ground pins PGND.

It should be appreciated that the second power device chip 202-2 has the same structure as the first power device chip 202-1, and is not discussed for the brevity of description.

The first winding 203-1 and the second winding 203-2 are embedded in the magnetic core 203-5 and have an upside-down “U” shape, and are parallel to each other. In the example shown in FIG. 4, the first winding 203-1 has a first portion 203-1a and a second portion 203-1b having ends 203-1ae and 203-1be connected out of the second surface 203-5b of the magnetic core 203-5, and has a middle portion 203-1c parallel to the first surface 203-5a of the magnetic core 203-5 and connecting the first portion 203-1a and the second portion 203-1b. The end 203-1ae of the first portion 203-1a of the first winding 203-1 connects out of the second surface 203-5b of the magnetic core 203-5 as shown in FIG. 5, and is connected to the first connecting pillar 202-3 embedded within the device substrate 202 by soldering or other connecting means as shown in FIG. 4. The end 203-1be of the second portion 203-1b of the first winding 203-1 connects out of the second surface 203-5b of the magnetic core 203-5 as shown in FIG. 5, and is connected to the second connecting pillar 202-4 embedded within the device substrate 202 by soldering or other connecting means as shown in FIG. 4. It should be appreciated that the second winding 203-2 has the similar structure with the first winding 203-1 as shown in FIG. 3, and has two ends 203-2ae and 203-2be connected to third connecting pillar 202-5 and the fourth connecting pillar 202-6 respectively.

The second portion 203-3b of the first inductor heat sink 203-3 partially covers the second surface 203-5b of the magnetic core 203-5 as shown in FIG. 5, and is attached to the die heat sink 202-7 directly or via a heat conductive contact 204 as shown in the example of FIG. 4. Similarly, the second portion 203-4b of the second inductor heat sink 203-4 partially covers the second surface 203-5b of the magnetic core 203-5 as shown in FIG. 5, and is attached to a die heat sink on top of the second power device chip 202-2 directly or via a heat conductive contact. In one embodiment, the inductor heat sinks 203-3 and 203-4 are made of copper, and dissipate heat from the die heat sinks on top of the power device chips 202-1 and 202-2. Consequently, the heat of the power device chips 202-1 and 202-2 are dissipated via the die heat sinks 202-7 and 202-8 and the inductor heat sink 203-3 and 203-4, respectively. The heat sinks 203-3 and 203-4 are attached to the magnetic core 203-5 by either thermal glue, thermal paste, or direct contact.

The first connecting pillar 202-3 has one end connecting out of the first surface 202-a of the device substrate 202 as shown in FIG. 6, and connected to the end of the first portion 203-1a of the first winding 203-1 as shown in FIG. 4, and has the other end connected to the bottom substrate 201 via a first switching terminal SSW1. Furthermore, the end of the first portion 203-1a of the first winding 203-1, and the first connecting pillar 202-3, are connected to the switching pin PSW1 of the first power device chip 202-1 via conductive traces inside the bottom substrate 201. Consequently, the heat of the first power device chip 202-1 is further dissipated through the first connecting pillar 202-3 and the first winding 203-1. The second connecting pillar 202-4 has one end connecting out of the first surface 202-a of the device substrate 202 and connected to the end of the second portion 203-1b of the first winding 203-1, and has the other end connected to the bottom substrate 201 via a first output voltage terminal SVOUT1. The third connecting pillar 202-5 has one end connecting out of the first surface 202-a of the device substrate 202 as shown in FIG. 6, and connected to the end 203-2ae of the first portion 203-2a of the second winding 203-2 shown in FIG. 5, and has the other end connected to the bottom substrate 201 via a second switching terminal SSW2. The end 203-2ae of the first portion 203-2a of the second winding 203-2, and the third connecting pillar 202-5, are connected to the switching pin PSW2 of the second power device chip 202-2 via conductive traces inside the bottom substrate 201. Consequently, the heat of the second power device chip 202-2 is further dissipated through the third connecting pillar 202-5 and the second winding 203-2. The fourth connecting pillar 202-6 has one end connecting out of the first surface 202-a of the device substrate 202 and connected to the end 203-2be of the second portion 203-2b of the second winding 203-2, and has the other end connected to the bottom substrate 201 via a second output voltage terminal SVOUT2. In some embodiments of the present invention, the connecting pillars 202-3˜202-6 are soldered to the bottom substrate 201, and the first switching terminal SSW1, the first output voltage terminal SVOUT1, the second switching terminal SSW2 and the second output voltage terminal SVOUT2 are solder pastes at the ends of the connecting pillars 202-3˜202-6. It should be appreciated that the connecting pillars 202-3˜202-6 may be connected to the bottom substrate 201 directly, or by other connecting means known in the art, e.g., the connecting pillars 202-3˜202-6 may be protruded out of the bottom surface 202-b of the device substrate 202, and are inserted to grooves of the bottom substrate 201.

As shown in FIG. 7, the first power device chip 202-1 has signal pins PSIG1 which may be configured to transmit temperature monitoring signal, current monitoring signal, and other necessary signals for communicating between the first power device chip 202-1 and external circuits. The second power device chip 202-2 has signal pins PSIG2 which may be configured to transmit temperature monitoring signal, current monitoring signal, and other necessary signals for communicating between the second power device chip 202-2 and external circuits. In FIG. 7, the driving pin PDRV1 is illustrated as an example of signal pins PSIG1, and the driving pin PDRV2 is illustrated as an example of signal pins PSIG2. Other signal pins, like the pins for transmitting the temperature monitoring signal, the current monitoring signal, etc., are not specifically labeled for brevity. The discrete components 202-p together with the power device chips 202-1 and 202-2 which are molded within the device substrate 202 have connecting terminals on the second surface of the device substrate 202. As shown in the embodiment of FIG. 7, each one of the discrete components 202-p, i.e., the capacitors and the resistors, has two pins or pads exposed on the second surface 202-b of device substrate 202, and connected to the bottom substrate 201, wherein the discrete components 202-p are connected to the power device chips 202-1, 202-2, and external components/circuits via the bottom substrate 201. Persons of ordinary skill in the art should know that the pins shown in FIG. 7 are for illustrating, which should not be limiting the present invention. The pin distribution on the second surface of the device substrate 202 is determined by the requirement of the application specs, and is varying in different applications.

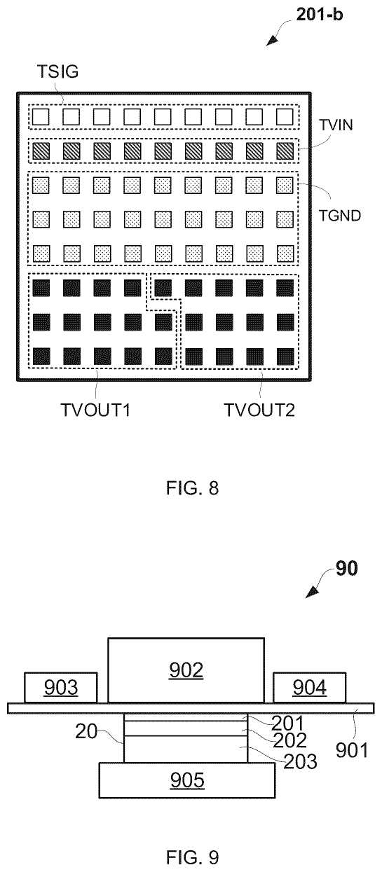

FIG. 8 shows a bottom view of the bottom substrate 201, i.e., the second surface 201-b of the bottom substrate 201, in accordance with an embodiment of the present invention. The second surface 201-b of the bottom substrate 201 includes a signal pad area TSIG, an input pad area TVIN, a ground pad area TGND, a first output voltage pad area TVOUT1 and a second output voltage pad area TVOUT2. Each one of the pad areas includes a plurality of pads. The pads on the second surface 201-b of the bottom substrate 201 connect through to the first surface 201-a of the bottom substrate 201 using, e.g., vias and conductive traces inside the bottom substrate 201. The plurality of pads of the signal pad area TSIG are connected to the signal pins PSIG1 of the first power device chip 202-1 and the signal pins PSIG2 of the second power device chip 202-2 respectively, like the driving pins PDRV1, PDRV2, temperature monitoring pins, etc. The plurality of pads of the input pad area TVIN are connected to the input pins PVIN of the first power device chip 202-1 and the second power device chip 202-2. The plurality of pads of the ground pad area TGND are connected to the ground pins PGND of the first power device chip 202-1 and the second power device chip 202-2. The plurality of pads of the first output voltage pad area TVOUT1 are connected to the end of the second portion 203-1b of the first winding 203-1 via the second connecting pillar 202-4. The plurality of pads of the second output voltage pad area TVOUT2 are connected to the end of the second portion 203-2b of the second winding 203-2 via the fourth connecting pillar 202-6. In one embodiment, the pads of the first output voltage pad area TVOUT1 and the pads of the second output voltage pad area TVOUT2 are disconnected, which makes the power module 20 work as two independent converters. In some embodiments, the pads of the first output voltage pad area TVOUT1 and the pads of the second output voltage pad area TVOUT2 are connected by external conductive traces or traces inside the bottom substrate, which makes the power module 20 work as a dual-phase power converter.

In the present invention, by stacking the bottom substrate 201, the device substrate 202 and the inductor assembly 203 vertically, the power density is increased. The first portions and the second portions of the first winding and the second winding are exposed to the side surfaces of the magnetic core as shown in the embodiments of the present invention. It should be appreciated that the first portions and the second portions of the first winding and the second winding could be totally embedded inside the magnetic core, thereby switching noise is shielded by the magnetic core 205 and the device substrate 202 of the power module 20, thus better noise immunity is provided compared to the prior art power modules.

In the present invention, the power device chips embedded within the device substrate dissipate heat from the top, i.e., through the die heat sinks, and meanwhile from the bottom, i.e., through the pins attached to the bottom substrate, and then further through the windings and magnetic core of the inductor assembly, which makes the heat dissipation performance excellent.

In one embodiment, the device substrate 202 is formed by firstly attaching the power device chips 202-1 and 202-2, the discrete components 202-p, and the connecting pillars 202-3˜202-6 to the bottom substrate 201, and secondly molding all the aforementioned components together. The power module 20 could be produced by stacking the inductor module 203 on top (first surface 202-a) of the device substrate 202, which highly eases the manufacturability and improves the robustness.

It should be appreciated that the device substrate 202 could also be implemented by other means, e.g., by PCB (Printed Circuit Board) process. Specifically, the power device chips 202-1 and 202-2, the discrete components 202-p, and the connecting pillars 202-3˜202-6 could be integrated in a PCB or be embedded by several PCB layers.

In one embodiment, the bottom substrate 201 is implemented by a PCB layer.

FIG. 9 is a side view illustrating a system 90 employing the power module 20 in accordance with an embodiment of the present invention. The system 90 includes a mainboard 901, a load 902, external components 903, 904, the power module 20, and a heat radiator 905. In the embodiment of FIG. 9, the load 902 and the power module 20 are attached to the opposite surfaces of the mainboard 901, which shorts the power delivery path, and improves the power efficiency. The load 902 may be a CPU, a GPU, or any other microprocessors. The power module 20 is attached to the mainboard 901 by the bottom substrate 201. The top of the power module 20 is covered by the heat radiator 905 for heat dissipation. The external components 903 and 904 may be the devices providing power, i.e., the input voltage Vin, or providing the phase control signals 105, to the power module 20. In other embodiments, the power module 20 and the load 902 may be placed on the same surface of the mainboard 901.

The power module for the dual-phase power converter is described for illustrating the present invention. It should be appreciated that the power module in the present invention could be scaled in by including a single power device chip and a single inductor to implement a single-phase power converter, or be scaled out by including more power device chips and inductors to implement multiple power converters or a multi-phase power converter.

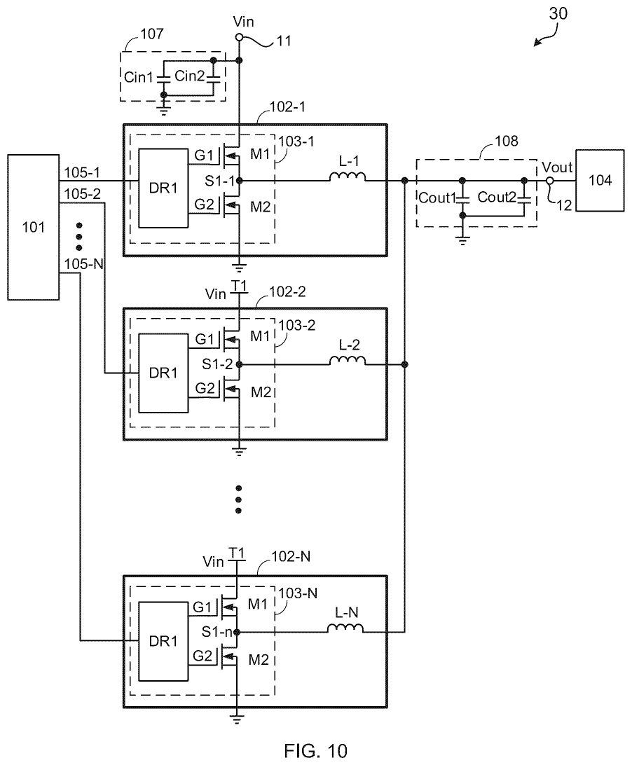

FIG. 10 schematically shows a multi-phase power converter 30 in accordance with an embodiment of the present invention. In the embodiment of FIG. 10, the input node 11 is configured to receive the input voltage Vin, and the output node 12 is configured to provide the output voltage Vout. Compared with the multi-phase power converter 10 shown in FIG. 1, the multi-phase power converter 30 further has an input capacitor pack 107 and an output capacitor pack 108. The input capacitor pack 107 has a plurality of capacitors coupled in parallel between the input node 11 and a reference ground. The embodiment of FIG. 10 shows two capacitors Cin1 and Cin2 as one example. However, one with ordinary skill in the art should understand that the number of the capacitors included in the input capacitor pack 107 is not limited by FIG. 10, the input capacitor pack 107 could also be implemented by more than two capacitors. The output capacitor pack 108 has a plurality of capacitors coupled in parallel between the output node 12 and the reference ground. The embodiment of FIG. 10 shows two capacitors Cout1 and Cout2 as one example. However, one with ordinary skill in the art should understand that the number of the capacitors included in the output capacitor pack 108 is not limited by FIG. 10, the output capacitor pack 108 could also be implemented by more than two capacitors.

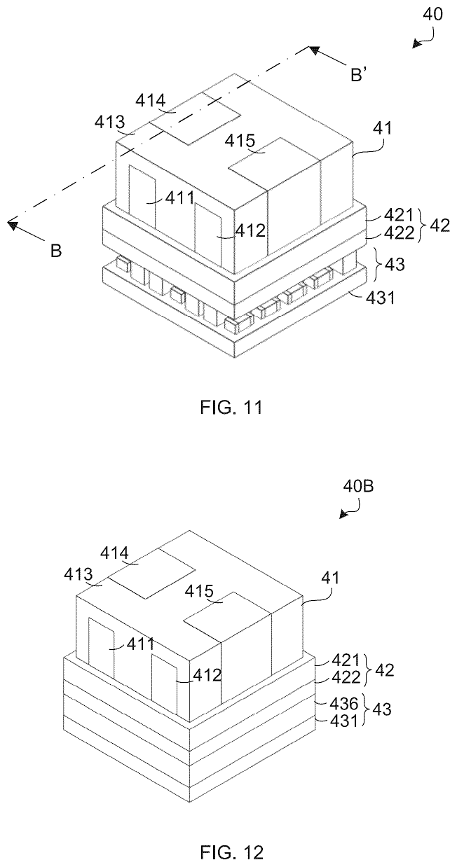

FIG. 11 shows a power module 40 in accordance with an embodiment of the present invention. In the embodiment of FIG. 11, the power module 40 comprises a dual-phase power converter, e.g., the power module 40 may integrate the power stage 102, the input capacitor pack 107, and the output capacitor pack 108 of FIG. 10, with N=2, for illustration purpose. In other words, in the example of FIG. 11, the power module 40 integrates the power blocks 103-1 and 103-2, the inductors L-1 and L-2, the input capacitor pack 107, and the output capacitor pack 108 shown in FIG. 10. One with ordinary skill in the art should understand that the phase number of the power module 40 is not limited by the embodiment of FIG. 11, the power module 40 may also comprise a power converter with more than two phases.

In the example of FIG. 11, the power module 40 has an inductor assembly 41, a die assembly layer 42 integrating the switches M1 and M2 of the power block 103-1 and the switches M1 and M2 of the power block 103-2, and a capacitor assembly layer 43. As shown in FIG. 11, the capacitor assembly layer 43 is disposed at bottom of the power module 40, the die assembly layer 42 is arranged above the capacitor assembly layer 43, and the inductor assembly 41 is disposed at top of the power module 40. The die assembly layer 42 has an upper surface and a lower surface which is opposite the upper surface. The capacitor assembly layer 43 is attached to the lower surface of the die assembly layer 42, and the inductor assembly 41 is attached to the upper surface of the die assembly layer 42. In the example of FIG. 11, the die assembly layer 42 has a die substrate 421 and a middle substrate 422, so that the lower surface of the die assembly layer 42 is also a lower surface of the middle substrate 422, and the upper surface of the die assembly layer 42 is also an upper surface of the die substrate 421. In one embodiment, at least one of the switches M1 and M2 of the power block 103-1 and at least one of the switches M1 and M2 of the power block 103-2 are embedded in the die substrate 421, and in another embodiment, one or more switches of the power blocks 103-1 and 103-2 may also be embedded in the middle substrate 422. The plurality of capacitors which form the input capacitor pack 107 and the plurality of capacitors which form the output capacitor pack 108 are disposed in the capacitor assembly layer 43 so that the input capacitor pack 107 and the output capacitor pack 108 are integrated in the power module 40. In the example of FIG. 11, the capacitor assembly layer 43 has a bottom substrate 431 at bottom of the power module 40, and the plurality of capacitors are disposed on an upper surface of the bottom substrate 431. In one embodiment, the middle substrate 422 and the bottom substrate 431 are implemented by printed circuit boards (PCBs).

In the example of FIG. 11, the inductor assembly 41 has a winding 411 and a winding 412 disposed on the upper surface of the die assembly layer 42. In one embodiment, the inductor assembly 41 further has a magnetic core 413 disposed on the upper surface of the die assembly layer 42. In one embodiment, the inductor assembly 41 further has inductor heat sinks 414-415 (which are also referred as heat sink layers in other embodiments described above) wrapping at least partial of the magnetic core 413 for heat dissipation of the power module 40.

FIG. 12 shows a power module 40B in accordance with another embodiment of the present invention. Compared with the power module 40 shown in FIG. 11, in the embodiment of FIG. 12, the plurality of capacitors which form the input capacitor pack 107 and the plurality of capacitors which form the output capacitor pack 108 are encapsulated in molding compound material 436. Compared with the power module 20 of FIGS. 2-3, input capacitors and output capacitors are further integrated in the power modules 40 and 40B. By vertically stacking the capacitor assembly layer 43, the die assembly layer 42, and the inductor assembly 41, the power modules 40 and 40B have a 3D stacking structure which is highly integrated. This structure greatly improves the power density and saves board space when applicated in supplying a CPU or GPU, etc.

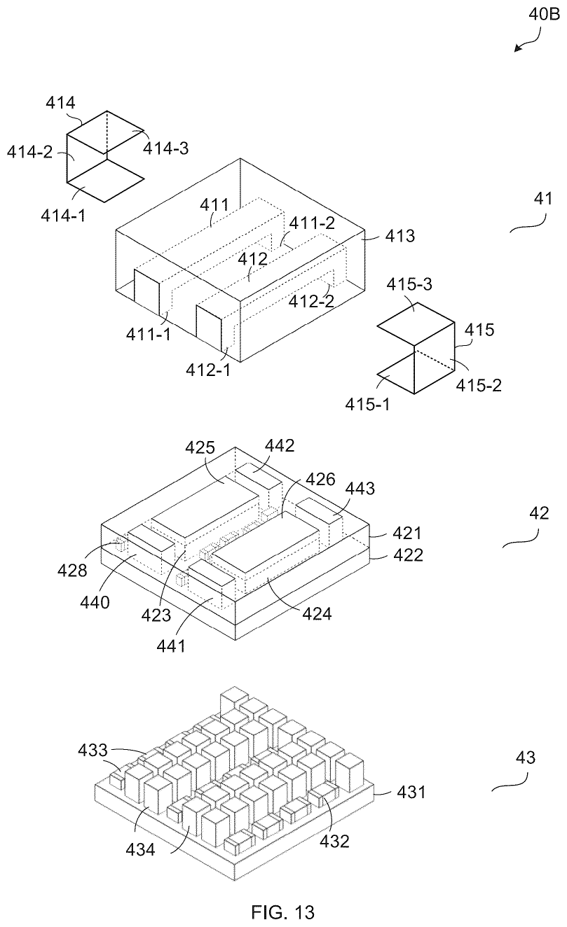

FIG. 13 shows a disassembled and perspective view illustrating the power module 40 of FIG. 11 in accordance with an embodiment of the present invention. As shown in FIG. 13, the winding 411 and the winding 412 are at least partially embedded in the magnetic core 413. In the embodiment of FIG. 13, the winding 411 and the winding 412 passes through the magnetic core 413 and are parallel to each other. In the embodiment of FIG. 13, the winding 411 and the magnetic core 413 form the inductor L-1 of the power converter 30, and the winding 412 and the magnetic core 413 form the inductor L-2 of the power converter 30. Each of the windings 411 and 412 has two ends attached to the upper surface of the die assembly layer 42. Furthermore, as shown in FIG. 13, each of the inductor heat sink 414 and the inductor heat sink 415 wraps partial of the magnetic core 413. To be specific, in the example of FIG. 13, each of the inductor heat sink 413 and the inductor heat sink 414 has a “C” shape with a portion attached to the first surface of the die assembly layer 42, E.g., the inductor heat sink 414 has three portions 414-1, 414-2, and 414-3, the inductor heat sink 415 has three portions 415-1, 415-2, and 415-3, and the portions 414-1 and 415-1 are attached to the first surface of the die assembly layer 42. As discussed above, the shapes of the windings 411-412 and the inductor heat sinks 414-415 may be varying in different applications.

In the example of FIG. 13, the power module 40 has a power integrated circuit (IC) die 423 and a power IC die 424 embedded in the die assembly layer 42. Power switches are integrated in the power IC die 423 and the power IC die 424. For example, in the power module 40, each of the power IC die 423 and the power IC die 424 integrates the switches M1 and M2 and the corresponding driver DR1, i.e., each of the power IC die 423 and the power IC die 424 integrates one power block 103. In one embodiment, the power IC dies 423 and 424 further integrate some auxiliary circuits not shown in FIG. 10. In the example of FIG. 13, the power IC die 423 is at least partially covered by a die heat sink 425 for heat dissipation, and the power IC die 424 is at least partially covered by a die heat sink 426 for heat dissipation. Each of the die heat sinks 425 and 426 (which are also referred as top heat layers in other embodiments described above) has a surface exposed at the upper surface of the die assembly layer 42.

In the example of FIG. 13, the die assembly layer 42 further has a connecting pillar 440 and a connecting pillar 441, which are coupled to the output node 12. In one embodiment, the power module 40B further has a connecting pillar 442 and a connecting pillar 443 embedded in the die assembly layer 42, wherein the connecting pillar 442 is electrically connected to a switch node S1-1, which is a common node of the switches M1 and M2 of the power block 103-1, and the connecting pillar 443 is electrically connected to a switch node S1-2, which is a common node of the switches M1 and M2 of the power block 103-2. The connecting pillars 440 and 442 are arranged at opposite sides of the power IC die 423, and the connecting pillars 441 and 443 are arranged at opposite sides of the power IC die 424. Each of the connecting pillars 440-443 has a first end exposed at the upper surface of the die assembly layer 42. In one embodiment, the power IC die 423, the power IC die 424, and the connecting pillars 440-443 are soldered to the middle substrate 422, and then encapsulated by molding compound to form the die substrate 421. In one embodiment, the power module 40 further has a plurality of passive devices 428 (e.g., resistors for the drivers DR1, and filter capacitors, etc.) embedded in the die assembly layer 42. It should be noted that not all of the passive devices 428 are labeled in FIG. 13 for clarity of illustration, and the layout of all the components disposed in the die assembly layer 42 is not limited by the example shown in FIG. 13.

As shown in FIG. 13, the winding 411 has a first end 411-1 attached to the first end of the connecting pillar 440 and a second end 411-2 attached to the first end of the connecting pillar 442, and the winding 412 has a first end 412-1 attached to the first end of the connecting pillar 441 and a second end 412-2 attached to the first end of the connecting pillar 443. Therefore, the first end 411-1 of the winding 411 and the first end 412-1 of the winding 412 are electrically connected to the output node 12, the second end 411-2 of the winding 411 is electrically connected to the switch node S1-1, and the second end 412-2 of the winding 412 is electrically connected to the switch node S1-2. In the embodiment of FIG. 13, the portion 414-1 of the inductor heat sink 414 is attached to the surface of the die heat sink 425, and the portion 415-1 of the inductor heat sink 415 is attached to the surface of the die heat sink 426, so that at least a portion of heat produced by the power IC die 423 is dissipated via the die heat sink 425 and the inductor heat sink 414, and at least a portion of heat produced by the power IC die 424 is dissipated via the die heat sink 426 and the inductor heat sink 415, as described above in FIG. 3 and FIG. 4.

In the embodiment of FIG. 13, the capacitor assembly layer 43 has a plurality of capacitors 432, a plurality of capacitors 433, and a plurality of connecting pillars 434 disposed on the upper surface of the bottom substrate 431, and the plurality of connecting pillars 434 are attached between the upper surface of the bottom substrate 431 and the lower surface of the die assembly layer 42 to provide electrical connection between the bottom substrate 431 and the die assembly layer 42. The plurality of capacitors 432 are electrically connected in parallel between the input node 11 and the reference ground via at least a portion of the plurality of connecting pillars 434, and thus form the input inductor pack 107 of the power converter 30 shown in FIG. 10. Similarly, the plurality of capacitors 433 are electrically connected between the output node 12 and the reference ground via at least a portion of the plurality of connecting pillars 434, and thus form the output inductor pack 108 of the power converter 30 shown in FIG. 10. I.e., each of the plurality of capacitors 432 has a first end electrically connected to the input node 11 and a second end electrically connected to the reference ground, and each of the plurality of capacitors 433 has a first end electrically connected to the output node 12 and a second end electrically connected to the reference ground. In another embodiment, the plurality of passive devices 428 embedded in the die assembly layer 42 may also comprise one or more capacitors electrically connected between the input node 11 and the reference ground, to form the input capacitor pack 107 together with the plurality of capacitors 432. In the example of FIG. 13, the plurality of connecting pillars 434 has one end attached to the upper surface of the bottom substrate 431 and another end attached to the lower surface of the die assembly layer 42, and each of the plurality of capacitors 432 and 433 has a height smaller than a height of the plurality of connecting pillars 434. In one embodiment, the plurality of connecting pillars 434 and the connecting pillars 440-443 are made of copper.

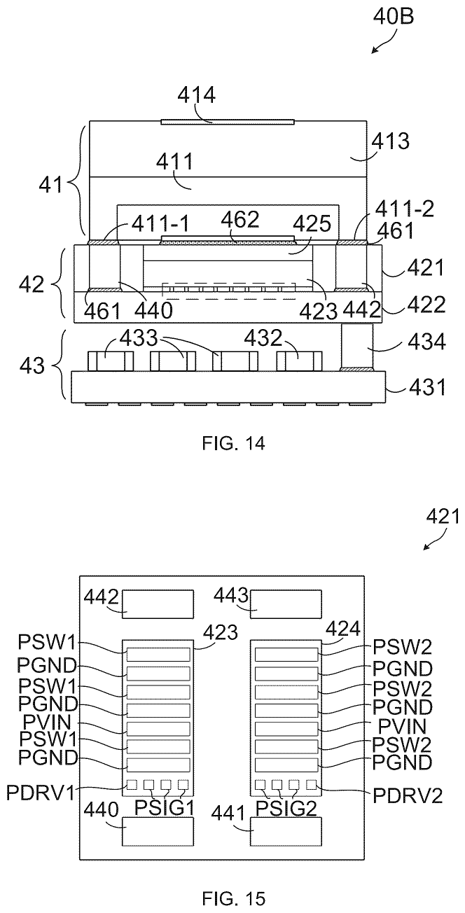

Physical and electrical connection in the power module 40B is further illustrated by FIGS. 14-17. FIG. 14 shows a cross-sectional view illustrating the power module 40 taken along BB' line of FIG. 11 in accordance with an embodiment of the present invention. As shown in FIG. 14, the power IC die 423 has a first surface covered by the die heat sink 425 and a second surface opposite its first surface. The power IC die 423 has a plurality of pins (marked in a box with dashed line) exposed at its second surface as shown in FIG. 14. In one embodiment, the power IC die 423 is soldered to the middle substrate 422 via the plurality of pins. Similarly, the power IC die 424 is soldered to the middle substrate 422 also via a plurality of pins, which is not shown in FIG. 14. In some embodiments, the plurality of pins of the power IC die 423 and 424 may comprise pads, bumps, ball grid arrays (BGA), or land grid arrays (LGA), etc. In one embodiment, the inductor heat sink 414 is attached to the surface of the die heat sink 425 directly or via a heat conductive contact 462 as shown in the example of FIG. 14. Similarly, the inductor heat sink 415 is attached to the surface of the die heat sink 426 directly or via the heat conductive contact 462 (not shown in FIG. 14). In some embodiments, the heat conductive contact 462 may comprise thermal glue, thermal paste, and thermal grease type or thermal putty type of dispensable materials, etc.

In the embodiment of FIG. 14, the winding 411 is soldered to the die assembly layer 42. To be specific, the first end 411-1 of the winding 411 is attached to the first end of the connecting pillar 440 via solder paste 461 to form electrical connection between the first end 411-1 of the winding 411 and the connecting pillar 440, and the second end 411-2 of the winding 411 is attached to the first end of the connecting pillar 442 via the solder paste 461 to form electrical connection between the second end 411-2 of the winding 411 and the connecting pillar 442. Similarly, in one embodiment, the connecting pillars 440-443 are soldered to the middle substrate 422, and the plurality of capacitors 432, the plurality of capacitors 433, and the plurality of connecting pillars 434 are also soldered to the bottom substrate 431. In a further embodiment, the plurality of connecting pillars 434 are also soldered between the bottom substrate 431 and the middle substrate 422.

FIG. 15 shows a bottom view of the die substrate 421 of the power module 40 in accordance with an embodiment of the present invention. As shown in FIG. 15, each of the connecting pillars 440-443 has a second end exposed at a lower surface of the die substrate 421, wherein the lower surface of the die substrate 421 is opposite the upper surface of the die substrate 421. In the embodiment of FIG. 15, the power IC die 423 has a pin PDRV1 to receive the control signal 105-1 for controlling the switches M1 and M2 of the power block 103-1, and the power IC die 424 has a pin PDRV2 to receive the control signal 105-2 for controlling the switches M1 and M2 of the power block 103-2. In the embodiment of FIG. 15, the power IC die 423 has at least one pin PSW1 electrically connected to the switch node S1-1, wherein the second terminal of the switch M1 and the first terminal of the switch M2 of the power block 103-1 are electrically connected together to form the switch node S1-1. Similarly, the power IC die 424 has at least one pin PSW2 electrically connected to the switch node S1-2 formed by the switch M1 and the switch M2 of the power block 103-2. In the embodiment of FIG. 15, each of the power IC dies 423 and 424 further has at least one pin PVIN and at least one pin PGND. The at least one pin PVIN of the power IC die 423 is electrically connected to the first terminal of the switch M1 of the power block 103-1, and the at least one pin PGND of the power IC die 423 is electrically connected to the second terminal of the switch M2 of the power block 103-1. The at least one pin PVIN of the power IC die 424 is electrically connected to the first terminal of the switch M1 of the power block 103-2, and the at least one pin PGND of the power IC die 424 is electrically connected to the second terminal of the switch M2 of the power block 103-2. In the example of FIG. 15, the pins PVIN of the power IC dies 423 and 424 are electrically connected to the input node 11 to receive the input voltage Vin, and the pins PGND of the power IC dies 423 and 424 are electrically connected to the reference ground. In one embodiment, the power IC die 423 further has at least one pin PSIG1 for communication between the power IC die 423 and external circuits, and the power IC die 424 further has at least one pin PSIG2 for communication between the power IC die 424 and the external circuits. FIG. 15 shows a layout of the plurality of pins of the power IC die 423 and the plurality of pins of the power IC die 424. However, one with ordinary skill in the art should understand that the numbers and layout of the plurality of pins of the power IC die 423 and the plurality of pins of the power IC die 424 are not limited by the example of FIG. 15.

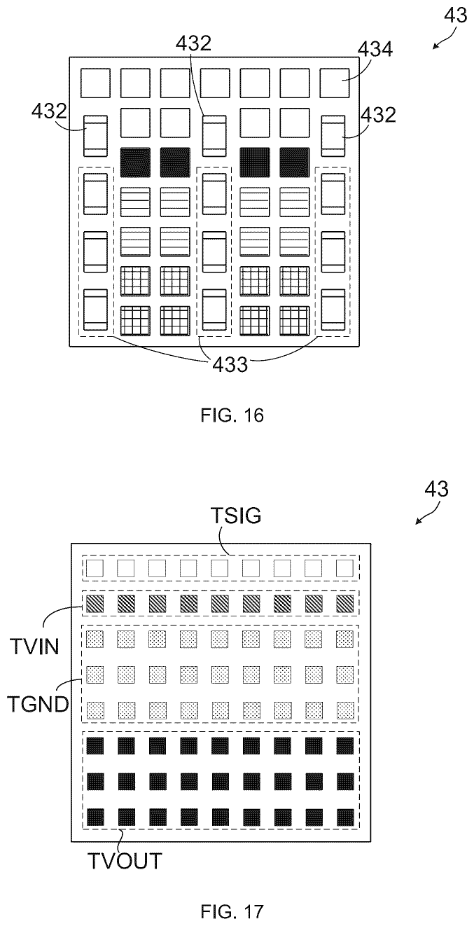

FIG. 16 shows a top view of the capacitor assembly layer 43 of the power module 40 in accordance with an embodiment of the present invention. The plurality of connecting pillars 434 are configured to conduct power and transmit the control signals, and as shown in FIG. 16, the plurality of connecting pillars 434 include different portions electrically connected to different nodes in the circuit of the power module 40, which are marked with different patterns for illustration purpose. For example, a first portion of the connecting pillars 434 (e.g., the connecting pillars marked in black) are electrically connected to the input node 11 to conduct the input voltage Vin, a second portion of the connecting pillars 434 (e.g., the connecting pillars marked with grid pattern) are electrically connected to the output node 12 to conduct the output voltage Vout, and a third portion of the connecting pillars 434 (e.g., the connecting pillars marked with horizontal line pattern) are electrically connected to the reference ground. Besides, a fourth portion of the connecting pillars 434 (e.g., the connecting pillars marked in white) are configured to transmit the control signals 105-1 and 105-2 for controlling the power blocks 103-1 and 103-2 and other signals (e.g., temperature monitoring signals).

In the embodiment of FIG. 16, the plurality of connecting pillars are symmetrically distributed on the bottom substrate 431 to form a space for placing the plurality of capacitors 432 and 433. It should be noted that although

FIG. 16 shows a layout of the plurality of capacitors 432, the plurality of capacitors 433, and the plurality of connecting pillars 434, one with ordinary skill in the art should understand that the numbers and layout of the plurality of capacitors 432, the plurality of capacitors 433, and the plurality of connecting pillars 434 are not limited by the example of FIG. 16.

FIG. 17 shows a bottom view of the capacitor assembly layer 43 in accordance with an embodiment of the present invention. As shown in FIG. 17, the power module 40 further has a plurality of pads disposed on a lower surface of the bottom substrate 431 for external connection, wherein the lower surface of the bottom substrate 431 is opposite the upper surface of the bottom substrate 431. In the embodiment of FIG. 17, The plurality of pads on the lower surface of the bottom substrate 431 comprise a plurality of pads TVIN electrically connected to the input node 11 to receive the input voltage Vin, a plurality of pads TGND electrically connected to the reference ground, a plurality of pads TVOUT electrically connected to the output node 12 to provide the output voltage Vout, and a plurality of pads TSIG for signal transmission between the power IC dies 423-424 and the external circuits. FIG. 17 shows a layout of the plurality of pads. However, one with ordinary skill in the art should understand that the numbers and layout of the plurality of pads are not limited by the example of FIG. 17.

In the embodiment of FIGS. 14-17, the components of the power module 40 are electrically connected to form the power converter 30 by way of electrical connection provided by the plurality of pins of the power IC dies 423-424, the connecting pillars 440-443, the plurality of connecting pillars 434, the middle substrate 422, the bottom substrate 431, and the plurality of pads on the bottom substrate 431.

For example, the input voltage Vin is conducted to the first ends of the plurality of capacitors 432 via the plurality of pads TVIN and the bottom substrate 431, and is provided to the power IC dies 423 and 424 further via the first portion of the connecting pillars 434, the middle substrate 422, and the pins PVIN of the power IC dies 423 and 424. The first end 411-1 of the winding 411 and the first end 412-1 of the winding 412 are electrically connected to the plurality of pads TVOUT to provide the output voltage Vout via the connecting pillars 440 and 441, the middle substrate 422, the second portion of the connecting pillars 434, and the bottom substrate 431, and the first ends of the plurality of capacitors 433 are also electrically connected to the plurality of pads TVOUT via the bottom substrate 431. The plurality of pads TGND, the pins PGND of the power IC dies 423 and 424, the second ends of the plurality of capacitors 432, and the second ends of the plurality of capacitors 433 are electrically connected together to form the reference ground of the power module 40 via the bottom substrate 431, the third portion of the plurality of connecting pillars 434, and the middle substrate 422. The second end 411-2 of the winding 411 is electrically connected to the switch node S1-1 via the connecting pillar 442, the die substrate 422, and the pins PSW1, and the second end 412-2 of the winding 412 is electrically connected to the switch node S1-2 via the connecting pillar 443, the die substrate 422, and the pins PSW2.

In one embodiment, the control signal 105-1 is transmitted to the power IC die 423 via at least one of the plurality of pads TSIG, the bottom substrate 431, at least one of the fourth portion of the plurality of connecting pillars 434, the middle substrate 422, and the pin PDRV1, and the control signal 105-2 is transmitted to the power IC die 424 via at least one of the plurality of pads TSIG, the bottom substrate 431, at least one of the fourth portion of the plurality of connecting pillars 434, the middle substrate 422, and the pin PDRV2. In a further embodiment, the power IC die 423 communicates with the external circuits via the pins PSIG1, the middle substrate 422, at least one of the fourth portion of the plurality of connecting pillars 434, the bottom substrate 431, and the plurality of pads TSIG, and the power IC die 424 communicates with the external circuits via the pins PSIG2, the middle substrate 422, at least one of the fourth portion of the plurality of connecting pillars 434, the bottom substrate 431, and the plurality of pads TSIG. In one embodiment, the electrical connection provided by the middle substrate 422 and the bottom substrate 431 comprises conductive traces and vias.

Obviously many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A power module, comprising:
a first layer comprising a first plurality of capacitors, a second plurality of capacitors, and a plurality of connecting pillars, wherein the first plurality of capacitors are electrically connected in parallel between an input node and a reference ground, and the second plurality of capacitors are electrically connected in parallel between an output node and the reference ground;
a second layer comprising a lower surface attached to the first layer, an upper surface opposite the lower surface, a first power IC die, and a second power IC die, wherein the first power IC die has a first pair of switches electrically connected between the input node and the reference ground, the second power IC die has a second pair of switches electrically connected between the input node and the reference ground; and
an inductor assembly attached to the upper surface of the second layer, wherein the inductor assembly comprises a magnetic core, a first winding passing through the magnetic core, and a second winding passing through the magnetic core, and wherein the first winding has a first end electrically connected to the output node and a second end electrically connected to a first switch node formed by the first pair of switches, and the second winding has a first end electrically connected to the output node and a second end electrically connected to a second switch node formed by the second pair of switches.

2. The power module of claim 1, wherein:
a first one of the plurality of connecting pillars is electrically connected to the input node;
a second one of the plurality of connecting pillars is electrically connected to the output node; and wherein
a third one of the plurality of connecting pillars is electrically connected to the reference ground.

3. The power module of claim 1, wherein the second layer further comprises:
a first die heat sink covering at least partial of the first power IC die; and
a second die heat sink covering at least partial of the second power IC die; wherein
each of the first die heat sink and the second die heat sink has a surface exposed at the upper surface of the second layer.

4. The power module of claim 3, wherein the inductor assembly further comprises a first inductor heat sink and a second inductor heat sink wrapping at least partial of the magnetic core, wherein:
the first inductor heat sink has a portion attached to the upper surface of the second layer covering at least partial of the first die heat sink, and the second inductor heat sink has a portion attached to the upper surface of the second layer covering at least partial of the second die heat sink.

5. The power module of claim 1, wherein the second layer further comprises a first connecting pillar and a second connecting pillar, and wherein:
the first connecting pillar has an end exposed at the upper surface of the second layer to be attached to the first end of the first winding, and the second connecting pillar has an end exposed at the upper surface of the second layer to be attached to the first end of the second winding; and wherein
the first connecting pillar and the second connecting pillar are electrically connected to the output node.

6. The power module of claim 5, wherein the second layer further comprises a third connecting pillar and a fourth connecting pillar, and wherein:
the third connecting pillar has an end exposed at the upper surface of the second layer to be attached to the second end of the first winding, and the fourth connecting pillar has an end exposed at the upper surface of the second layer to be attached to the second end of the second winding; and wherein
the third connecting pillar is electrically connected to the first switch node, and the fourth connecting pillar is electrically connected to the second switch node.

7. The power module of claim 1, wherein the first layer further comprises a bottom substrate having an upper surface and a lower surface opposite the upper surface of the bottom substrate, wherein:
the first plurality of capacitors and the second plurality of capacitors are disposed on the upper surface of the bottom substrate, and the plurality of connecting pillars are disposed between the upper surface of the bottom substrate and the lower surface of the second layer to provide electrical connection between the bottom substrate and the second layer.

8. The power module of claim 7, wherein the first layer further comprises a plurality of pads disposed on the lower surface of the bottom substrate, and wherein the plurality of pads comprises:
a first pad electrically connected to the input node for receiving an input voltage;
a second pad electrically connected to the output node for providing an output voltage;
a third pad electrically connected to the reference ground;
a fourth pad electrically connected to the first power IC die, wherein the fourth pad is configured to receive a first control signal for controlling the first pair of switches; and
a fifth pad electrically connected to the second power IC die, wherein the fifth pad is configured to receive a second control signal for controlling the second pair of switches.

9. The power module of claim 1, wherein:
the first power IC die further comprises a first pin configured to receive a first control signal for controlling the first pair of switches, a second pin electrically connected to the first switch node, a third pin electrically connected to the input node, and a fourth pin electrically connected to the reference ground; and wherein
the second power IC die further comprises a first pin configured to receive a second control signal for controlling the second pair of switches, a second pin electrically connected to the second switch node, a third pin electrically connected to the input node, and a fourth pin electrically connected to the reference ground.

10. The power module of claim 9, wherein:
a fourth one of the plurality of connecting pillars is electrically connected to the first pin of the first power IC die for transmitting the first control signal; and
a fifth one of the plurality of connecting pillars is electrically connected to the first pin of the second power IC die to transmit the second control signal.

11. A power module, comprising:
a first layer comprising a first plurality of capacitors, a second plurality of capacitors, and a plurality of connecting pillars, wherein the first plurality of capacitors are electrically connected in parallel between an input node and a reference ground, and the second plurality of capacitors are electrically connected in parallel between an output node and the reference ground;
a second layer comprising a lower surface attached to the first layer, an upper surface opposite the lower surface, a first pair of switches, and a second pair of switches, wherein the first pair of switches are electrically connected between the input node and the reference ground, and the second pair of switches are electrically connected between the input node and the reference ground; and
an inductor assembly attached to the upper surface of the second layer, comprising a first inductor and a second inductor, wherein the first inductor is electrically connected between the output node and a first switch node formed by the first pair of switches, and the second inductor is electrically connected between the output node and a second switch node formed by the second pair of switches.

12. The power module of claim 11, wherein:
a first one of the plurality of connecting pillars is electrically connected to the input node;
a second one of the plurality of connecting pillars is electrically connected to the output node; and wherein
a third one of the plurality of connecting pillars is electrically connected to the reference ground.

13. The power module of claim 11, wherein:
a fourth one of the plurality of connecting pillars is configured to transmit a first control signal to the second layer, and a fifth one of the plurality of connecting pillars is configured to transmit a second control signal to the second layer; and wherein
the first control signal is configured to control the first pair of switches, and the second control signal is configured to control the second pair of switches.

14. The power module of claim 11, wherein:
the second layer further comprises a first substrate and a second substrate, and wherein at least one of the first pair of switches and at least one of the second pair of switches are embedded in the first substrate.

15. The power module of claim 11, wherein the inductor assembly further comprises a magnetic core disposed on the upper surface of the second layer, and wherein:
the first inductor comprises a first winding passing through the magnetic core, and the second inductor comprises a second winding passing through the magnetic core.

16. The power module of claim 11, wherein each of the first layer and the second layer further comprises a printed circuit board (PCB).

17. A power module, comprising:
a capacitor assembly layer disposed at bottom of the power module, comprising a bottom substrate, a first plurality of capacitors, and a second plurality of capacitors, wherein the first plurality of capacitors and the second plurality of capacitors are disposed on the bottom substrate, and wherein the first plurality of capacitors are electrically connected in parallel between an input node and a reference ground, and the second plurality of capacitors are electrically connected in parallel between an output node and the reference ground;
a first pair of switches electrically connected between the input node and the reference ground;
a second pair of switches electrically connected between the input node and the reference ground; and
an inductor assembly disposed at top of the power module, comprising a magnetic core, a first winding at least partially embedded in the magnetic core, and a second winding at least partially embedded in the magnetic core, wherein the first winding is electrically connected between an output node and a first switch node formed by the first pair of switches, and the second winding is electrically connected between the output node and a second switch node formed by the second pair of switches.

18. The power module of claim 17, wherein the capacitor assembly layer further comprises a plurality of connecting pillars, and wherein:
a first one of the plurality of connecting pillars is electrically connected to the input node;
a second one of the plurality of connecting pillars is electrically connected to the output node; and
a third one of the plurality of connecting pillars is electrically connected to the reference ground.
